(19) United States
(12) Patent Application Publication
(10) Pub. No.: US 2026/0136485 A1
(43) Pub. Date: May 14, 2026

(54) ELECTRONIC DEVICE PORT EJECTION STRUCTURE

(71) Applicants: HON HAI PRECISION INDUSTRY CO., LTD., New Taipei (TW); HONGFUJIN PRECISION INDUSTRY (WUHAN) CO., LTD., Wuhan (CN)

(72) Inventors: Chin-Chi LIN, New Taipei (TW); Tzu-Hsuan HUANG, New Taipei (TW); Chinh-Chiang YANG, New Taipei (TW); Chien-Cheng HUANG, New Taipei (TW)

(21) Appl. No.: 18/989,256

(22) Filed: Dec. 20, 2024

(30) Foreign Application Priority Data
Nov. 8, 2024 (CN) 202422727852.2

(51) Int. Cl. H05K 5/02; G06K 13/08

(52) U.S. Cl. CPC H05K 5/0295; G06K 13/0818

(57) ABSTRACT

An electronic device port ejection structure includes a first mounting member, a moving assembly, and a first resilient member. The first mounting member is connected to the electronic device, and the first mounting member is provided with a holding groove, a first damping portion is provided on an inner wall of the holding groove. Along a first direction, the moving assembly is slidably coupled to the first mounting member, and the moving assembly is configured to be at least partially slidable relative to the first mounting member to enter the holding groove. A second damping portion is provided on the moving assembly and during sliding of the moving assembly relative to the first mounting member, the second damping portion contacts the first damping portion and creates damping. The first resilient member is configured to provide a first resilient force on the moving assembly.

### FIELD

The subject matter relates to the field of electronic device, and in particular to an electronic device port ejection structure.

### BACKGROUND

Electronic devices have a wide range of applications in various fields. Some electronic devices are provided with ports for connecting with other electronic devices, and the ports may be provided on an ejector structure according to the needs, so that the ports are hidden when the ejector structure is pushed into the structure of the electronic device when not in need of use, and the ports are revealed and can be used when the ejector structure is ejected when in need of use. However, current ejection structures generally employ dampers to decelerate when ejecting the ejection structure, which is costly.

### SUMMARY

Embodiments of the present application provide a low cost port pop-out structure for electronic devices.

Embodiments of the present application provide an electronic device port ejection structure for connecting with an electronic device, the electronic device port ejection structure includes a first mounting member, a moving assembly and a first resilient member. The first mounting member is connected to the electronic device, the first mounting member is provided with a holding groove, and a first damping portion is provided on an inner wall of the holding groove. Along a first direction, the moving assembly is slidably coupled to the first mount, the moving assembly is configured to be at least partially slidable with respect to the first mount into the holding groove; the moving assembly is provided with a second damping portion, the second damping portion is in contact with the first damping portion and creating damping during sliding of the moving assembly with respect to the first mount. The first resilient member is configured to provide a first resilient force on the moving assembly to drive the moving assembly out of the holding groove.

It will be appreciated that the provision of the first damping portion on the inner wall of the holding groove and the second damping portion on the moving assembly can generate damping during sliding of the moving assembly with respect to the first mounting member, so as to decelerate the sliding process of the moving assembly with respect to the first mounting member. The provision of the damping portion eliminates the need for a damper in the structure and reduces production costs, while still achieving the effect of decelerating the ejection of the component.

In one embodiment, the first resilient member includes a first bending portion, a compression portion, and a second bending portion connected in sequence, the first bending portion is connected to the first mounting member, and the second bending portion is connected to the moving assembly.

Wherein the first bending portion and the second bending portion are rotatably relative to the compression portion during sliding of the moving assembly relative to the first mounting member, to elastically deform the compression portion to provide a first elastic force.

In one embodiment, the moving assembly includes a second mounting member, the second damping portion includes a first projection, the first projection is disposed on the second mounting member, the first projection rests against at least a side of the first mounting member along a second direction during sliding of the moving assembly with respect to the first mounting member, the second direction intersects the first direction.

In one embodiment, a plurality of the first projections are spaced apart along the first direction.

In one embodiment, the electronic device port ejection structure further includes a limit assembly, along the first direction, the limit assembly is configured to limit movement of the moving assembly.

In one embodiment, the limit assembly includes a limit member, the limit member is connected to the first mounting member. The second mounting member is provided with a limit hole, the limit member is configured to rest against a wall of the limit hole aperture along the second direction, and the limit member is movable in the limit hole along the first direction.

In an embodiment, along a third direction, the limit member is configured to resist the second mounting member, the third direction intersects the first direction, and the third direction intersects the second direction.

In one embodiment, the first damping portion comprises a second projection, the second projection is disposed on the first mounting member, the second projection rests against at least a side of the moving assembly along a second direction during sliding of the moving assembly relative to the first mounting member, the second direction intersects the first direction.

In one embodiment, a plurality of the second projections are spaced apart along the first direction.

In one embodiment, the electronic device port ejection structure further includes a locking assembly, the moving assembly includes a locked member, the locking assembly lock the locked member along the first direction when the locked member is moved to a point where it is partially located within the locking assembly, the locking assembly lock the locked member, the locked member continue to move in a direction deeper into the locking assembly, the locking assembly unlocks the locked member and the locked member is releasable from the locking assembly.

### BRIEF DESCRIPTION OF THE DRAWINGS

FIG. 1 shows a three-dimensional schematic view of an electronic device port ejection structure.

FIG. 2 shows an exploded view of the electronic device port ejection structure shown in FIG. 1.

FIG. 3 shows a three-dimensional schematic view of the electronic device port ejection structure shown in FIG. 1 connected to an electronic device.

FIG. 4 shows a three-dimensional schematic view of a first mounting member of the electronic device port ejection structure.

FIG. 5 shows a three-dimensional schematic view of a moving assembly of the electronic device port ejection structure.

FIG. 6 shows a cross-sectional view of a locking assembly of the electronic device port ejection structure.

FIG. 7 shows a schematic view of a backside of the locking assembly of the electronic device port ejection structure.

### DETAILED DESCRIPTION

The following description will refer to the accompanying drawings for a more complete description of the present application. Exemplary embodiments of the present application are shown in the accompanying drawings. However, the present application can be implemented in many different forms and should not be construed as limited to the exemplary embodiments set forth herein. These exemplary embodiments are provided to make the present application thorough and complete and to adequately convey the scope of the present application to those skilled in the art. Similar accompanying drawings are labeled to indicate the same or similar components. The terminology used herein is used only for the purpose of describing particular exemplary embodiments and is not intended to limit the present application. As used herein, the singular forms “one,” “a,” and “the” are intended to include the plural form as well, unless the context clearly indicates otherwise. In addition, when used herein, “including” and/or “comprising” and/or “having”, integers, steps, operations, components and/or assemblies does not preclude the presence or addition of one or more other features, regions, integers, steps, operations, components and/or groups thereof. Unless otherwise defined, all terms used herein, including technical and scientific terms, have the same meaning as commonly understood by those of ordinary skill in the art to which this application belongs. Furthermore, unless expressly defined in the text, terms such as those defined in general-purpose dictionaries should be construed as having a meaning consistent with their meaning in the relevant art and in the contents of this application, and will not be construed as having an idealized or overly formalized meaning.

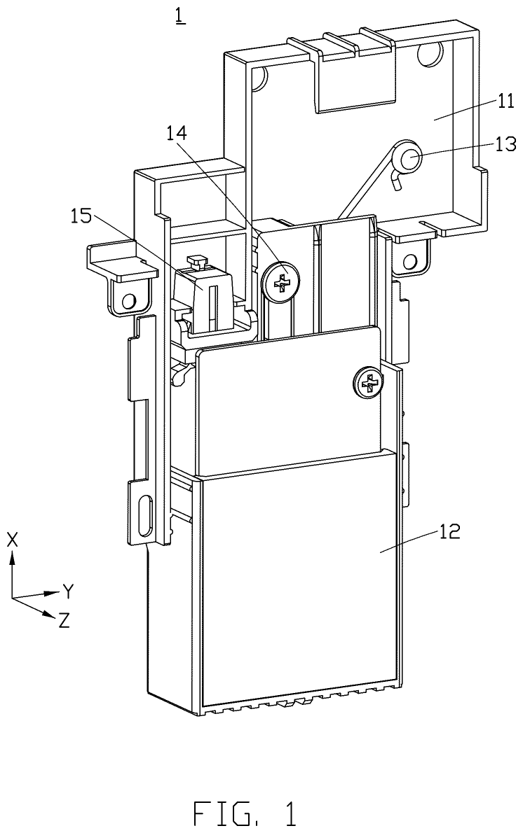

As shown in FIGS. 1 to 3, an embodiment of the present application provides an electronic device port ejector structure 1 for connecting with an electronic device 2. The electronic device port ejector structure 1 includes a first mounting member 11, a moving assembly 12, and a first resilient member 13.

In order to facilitate subsequent reading, the present application introduces a first direction X, a second direction Y and a third direction Z to describe the embodiments of the present application. The first direction X, the second direction Y and the third direction Z may be three mutually non-parallel linear directions in space; further, the first direction X, the second direction Y and the third direction Z may be three mutually perpendicular directions in a three-dimensional coordinate system (three-dimensional Cartesian coordinate system). In subsequent embodiments, the first direction X is the X-axis direction of the coordinate axis of the three-dimensional coordinate system, the second direction Y is the Y-axis direction of the coordinate axis of the three-dimensional coordinate system, and the third direction Z is the Z-axis direction of the coordinate axis of the three-dimensional coordinate system, as an example, are described.

The first mounting member 11 is connected to the electronic device 2, the first mounting member 11 is provided with a holding groove 110, and a first damping portion 111 is provided on an inner wall of the holding groove 110. The moving assembly 12 is slidably connected to the first mounting member 11 along the first direction X. At least a part of the moving assembly 12 is slidable with respect to the first mounting member 11 to enter into the holding groove 110. A second damping portion 121 is provided on the moving assembly 12, and during sliding of the moving assembly 12 relative to the first mounting member 11, the second damping portion 121 comes into contact with the first damping portion 111 and creates damping. The first resilient member 13 is configured to provide a first elastic force on the moving assembly 12 to drive the moving assembly 12 out of the holding groove 110.

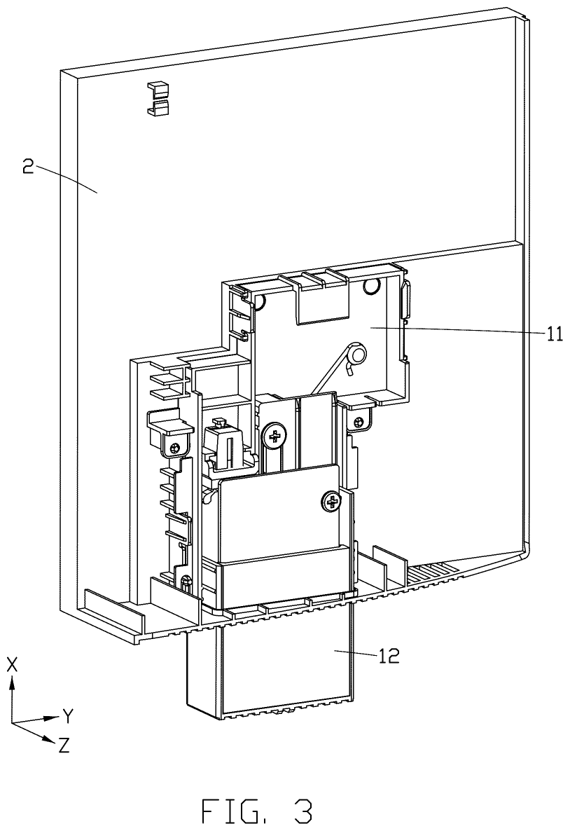

In this embodiment, the electronic device 2 may be a display, and a portion of the display is shown in FIG. 3. The electronic device port ejector structure 1 is mounted on the electronic device 2 via the first mounting member 11, and screws may be used to connect the first mounting member 11 and the electronic device 2, and the specific mounting form may be selected according to the actual situation. The moving assembly 12 may be provided with ports for connection to other electronic devices. The first mounting member 11 may be in the form of a plate, which is capable of being mounted with the electronic device 2. It is sufficient that the first damping portion 111 and the second damping portion 121 are capable of increasing the friction when sliding between the moving assembly 12 and the first mounting member 11, and there is no excessive restriction herein. The is one first resilient member 13.

The holding groove 110 is disposed on an end surface of one end of the first mounting member 11 along the first direction X, and the holding groove 110 extends along the first direction X but does not extend through the first mounting member 11. The moving assembly 12 may slide from an open end of the holding groove 110 to enter the holding groove 110. In addition, along the third direction Z, the holding groove 110 may extend upwardly through the first mounting member 11, to accommodate a situation where the thickness of the moving assembly 12 exceeds the depth of the holding groove 110 along the third direction Z.

It will be appreciated that the first damping portion 111 on the inner wall of the holding groove 110 and the second damping portion 121 on the moving assembly 12 can generate damping during the sliding process of the moving assembly 12 with respect to the first mounting member 11, which can decelerate the sliding process of the moving assembly 12 with respect to the first mounting member 11. The provision of the damping portion eliminates the need for a damper in the structure and reduces production costs, while still achieving the effect of decelerating the ejection of the component. Moreover, only one first resilient member 13 is provided in this application, which occupies less space and can be suitable for use in smaller spaces.

In an embodiment, the first resilient member 13 includes a first bending portion 131, a compression portion 132, and a second bending portion 133 connected in sequence, the first bending portion 131 is connected to the first mounting member 11, and the second bending portion 133 is connected to the moving assembly 12.

Wherein, during sliding of the moving assembly 12 relative to the first mounting member 11, the first bending portion 131 and the second bending portion 133 are rotatable relative to the compression portion 132 to elastically deform the compression portion 132 to deform elastically and provide the first elastic force.

In this embodiment, the first resilient member 13 is disposed within the holding groove 110, the first bending portion 131 is attached to an inner wall of the holding groove 110, and the second bending portion 133 may be directly attached to the moving assembly 12 or may be disposed in the path of the moving assembly 12 and may be held against the moving assembly 12.

The first resilient member 13 may be selected as a torsion spring, the torsion spring is able to provide sufficient elastic force to the moving assembly 12 during sliding of the moving assembly 12 relative to the first mounting member 11. Other resilient members include the first bending portion 131, the compression portion 132, and the second bending portion 133 may also be selected, and the resilient member may be deflected in the compression process to save space, without being overly limited herein.

It is to be understood that the setting of the first resilient member 13 adopting a torsion spring makes the first resilient member 13 occupy less space, so that the volume of the electronic device port ejection structure 1 can be reduced, which is suitable for the case of less space. At the same time, the torsion spring can provide sufficient elastic force to the moving assembly 12 to ensure the movement of the moving assembly 12 with respect to the first mounting member 11, which can ensure that the moving assembly 12 can eject.

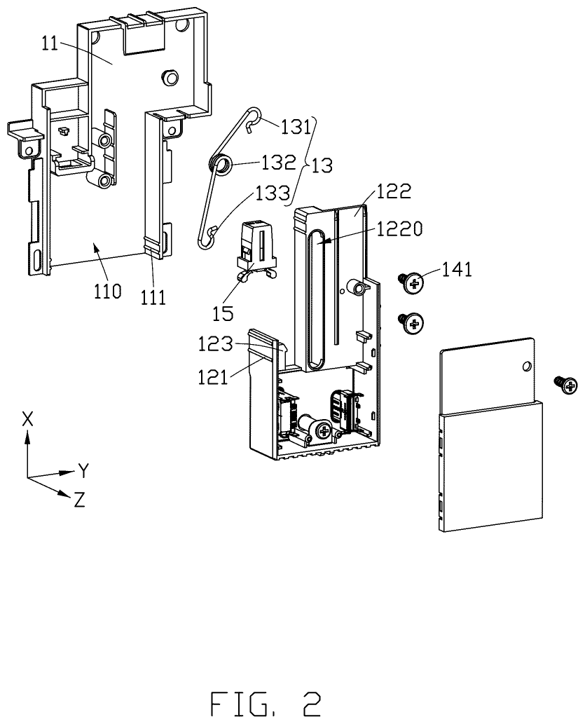

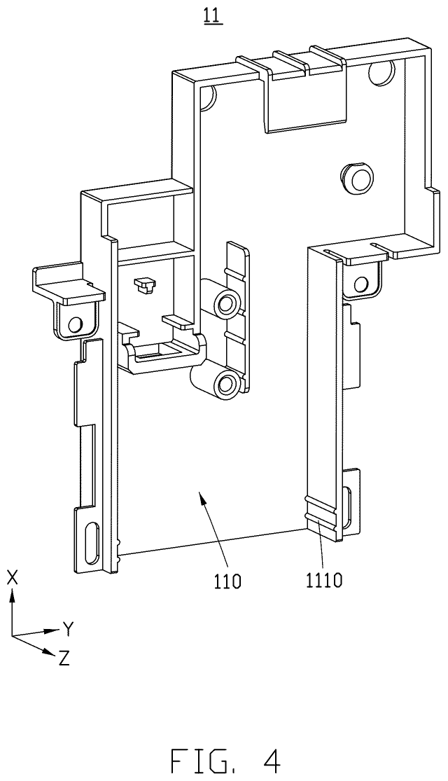

In one embodiment, as shown in FIGS. 2, 4, and 5, the moving assembly 12 includes a second mounting member 122, the second damping portion 121 includes a first projection 1210, the first projection 1210 is disposed on the second mounting member 122, and the first projection 1210 resists at least one side of the first mounting member 11 along the second direction Y during the sliding of the moving assembly 12 relative to the first mounting member 11.

In this embodiment, along the first direction X, the second mounting member 122 is slid relative to the first mounting member 11 to slide the moving assembly 12 relative to the first mounting member 11. The first projection 1210 may be integrally molded with the second mounting member 122.

It is to be understood that the provision of the first projection 1210 increases the friction of the second mounting member 122 when sliding with respect to the first mounting member 11, while the integrally molded first projection 1210 and the second mounting member 122 are more convenient to produce and can reduce the cost.

In other embodiments, the first projection 1210 and the second mounting member 122 are separately molded. The first projection portion 1210 and the second mounting member 122 may be connected during use as appropriate.

In one embodiment, a plurality of the first projections 1210 are spaced apart along the first direction X.

It will be appreciated that the plurality of first projections 1210 at intervals can further increase friction and decelerate the speed of the moving assembly 12 when it slides with respect to the first mounting member 11, so that the moving assembly 12 can move at a more appropriate speed during use.

In an embodiment, the first damping portion 111 includes a second projection 1110, the second projection 1110 is disposed on the first mounting member 11, and the second projection 1110 resists at least one side of the moving assembly 12 along the second direction Y during sliding of the moving assembly 12 relative to the first mounting member 11.

In this embodiment, along the second direction Y, the second projections 1110 are provided on opposite two inner walls of the holding groove 110, and first projections 1210 are projected on opposite sides of the second mounting member 122.

During sliding of the moving assembly 12 relative to the first mounting member 11, the first projection 1210 and the second projection 1110 will be held against each other along the first direction X to apply sliding damping to the sliding of the second mounting member 122. However, the second mounting member 122 may overcome the sliding damping and slide over the second projection 1110 under an external force. The second projection 1110 is integrally molded with the first mounting member 11.

It is understood that the provision of the second projection 1110 further increases the friction within the moving assembly 12 and the first mounting member 11, reduces the sliding speed of the moving assembly 12, and avoids the sliding speed of the moving assembly 12 from being too large. At the same time, the integrally molded second projection 1110 and the first mounting member 11 are more convenient and reduce production costs during production.

In other examples, the second damping portion 121 includes the first projection 1210, or the first damping portion 111 includes the second projection 1110, and at this time the damping portion which is not provided with a projection may be provided with other damping-generating components, and it is sufficient to be able to generate damping between the first damping portion 111 and the second damping portion 121 during the sliding process, and it will not be overly limited herein. The second projection portion 1110 may be connected with the first mounting member 11 as a split connection, which may be set according to the actual situation.

In one embodiment, a plurality of the second projections 1110 are spaced apart along the first direction X.

It will be appreciated that the plurality of second projections 1110 at intervals can further increase friction and decelerate the speed of the moving assembly 12 when it slides with respect to the first mounting member 11, so that the moving assembly 12 can move at a more appropriate speed during use.

In one embodiment, as shown in FIGS. 1 and 2, the electronic device port ejector structure 1 further comprises a limit assembly 14. Along the first direction X, the limit assembly 14 is configured to limit movement of the moving assembly 12.

In this embodiment, along the first direction X, the limit assembly 14 is provided with a limited path of movement, such that the moving assembly 12 can only move in that limited path.

It is to be understood that the provision of the limit assembly 14 makes the displacement of the moving assembly 12 in the first direction X limited, ensuring that the moving assembly 12 will not be displaced excessively due to the first elastic force provided by the first resilient member 13, and avoiding the moving assembly 12 from moving out of the first mounting member 11.

In one embodiment, the limit assembly 14 includes a limit member 141, the limit member 141 is coupled to the first mounting member 11. The second mounting member 122 is provided with a limit hole 1220, and along the second direction Y, the limit member 141 is configured to rest against the wall of the limit hole 1220. And along the first direction X, the limit member 141 is movable in the limit hole 1220.

In this embodiment, the limit member 141 may be selected as a rod, which may be disposed in the limit hole 1220 and move along the first direction X. The projected shape of the limit hole 1220 in a plane parallel to the plane in which it is located may be rectangular, and both sides of the limit member 141 along the second direction Y are held against the wall of the limit hole 1220, such that the limit member 141 is limited in the second direction Y. The projected shapes of the ends of the limit hole 1220 along the first direction X on a plane parallel to the plane in which it is located may also be further set as arcs according to the shape of the limit member 141, such as a rod, so that the limit member 141 is adhered to the wall of the limit hole 1220 more well.

It will be appreciated that the limit member 141 is constrained to move only in the limit hole 1220, with a limited path of movement in the first direction X and a limited displacement in the second direction Y, to make the moving assembly 12 reliable during movement.

In one embodiment, along the third direction Z, the limit member 141 is configured to rest against the second mounting member 122.

In this embodiment, the limit member 141 may be selected as a bolt with a screw disposed in the limit hole 1220. Along the third direction Z, the nut rests against the second mounting member 122, to limit displacement of the limit member 141 in the third direction Z. Two limit member 141 may be spaced apart, with the two limit members 141 resting against the walls of the ends of the limit holes 1220 along the first direction X during movement. The limit members 141 may be split-molded, with a screw sleeve fixedly connected to the first mounting member 11 and a bolt threaded with the screw sleeve to form the limit members 141, the split-molded limit members 141 is easy to install.

It can be understood that the limit member 141 adopts a bolt to limit the limit member 141 in both the second direction Y and the third direction Z, which can only be moved along the first direction X to ensure that the moving assembly 12 is reliable when it is ejected. The movement distance between the two limit members 141 in the first direction X according to the actual situation.

In other embodiments, there is one limit member 141.

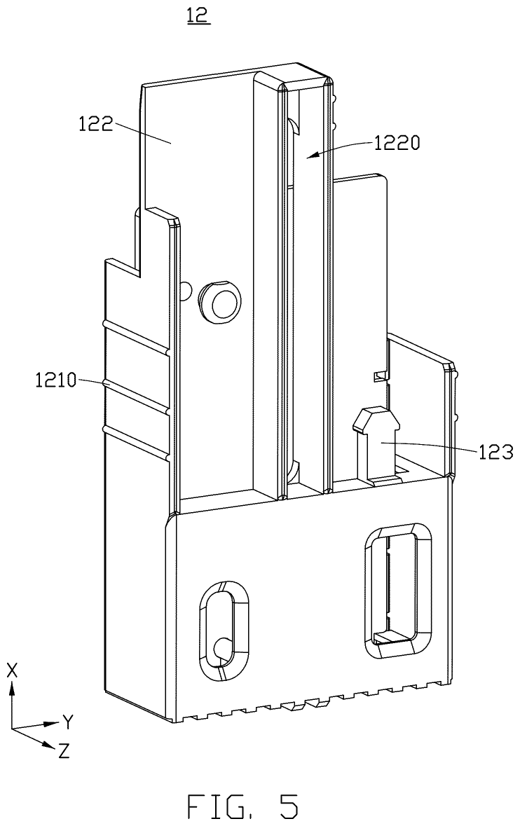

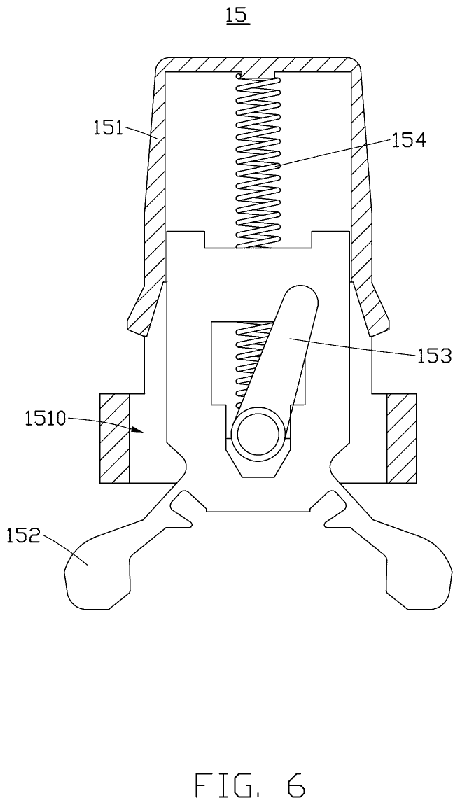

In one embodiment, as shown in FIGS. 5 and 6, the electronic device port ejector structure 1 further includes a locking assembly 15, the moving assembly 12 includes a locked member 123. Along the first direction X, the locked member 123 moves until it is partially disposed within the locking assembly 15, the locking assembly 15 locks the locked member 123, and along the direction of penetrating into the locking assembly 15, the locked member 123 continues to move, and the locking assembly 15 releases the locked member 123, and the locked member 123 may be disengaged from the locking assembly 15.

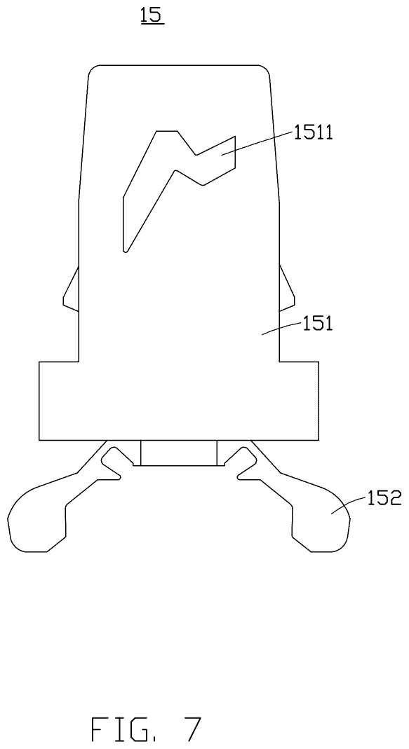

In this embodiment, as shown in FIGS. 5 to 7, the locking assembly 15 includes a housing 151, a locking member 152, a guide member 153, and a second resilient member 154. The guide member 153 is coupled to the locking member 152, the housing 151 is provided with an accommodating groove 1510, the locking member 152 is partially accommodated within the accommodating groove 1510, and the second resilient member 154 is held against the locking member 152. Along the first direction X, the locked member 123 may rest against and be locked by the locking member 152, and the second resilient member 154 provides a second elastic force on the locking member 152, the second elastic force is configured to drive the locking member 152 out of the accommodating groove 1510. The second resilient member 154 may be selected from a spring or a compression spring, etc. The guide member 153 is connected to the locking member 152, and the housing 151 is provided with a guide hole 1511, the guide hole 1511 is connected to the accommodating groove 1510, and the guide member 153 may be moved in an extension direction of the guide hole 1511 driven by the locking member 152.

When the locked member 123 moves along the first direction X and drives the locking member 152, the locking member 152 and the locked member 123 are accommodated in the accommodating groove 1510, and the locked member 123 is locked, at which time the guide member 153 is limited in the guide hole 1511, which drives the locking member 152 and is no longer moved. When a force is externally applied to the locked member 123 again and the locked member 123 moves the locking member 152 along the first direction X, the guide member 153 moves in the guide hole 1511 and is no longer limited, and at this time, the second resilient member 154 provides the second resilient force to drive the locking member 152 out of the accommodating groove 1510, and the locking member 152 drives the locked member 123 out of the accommodating groove 1510 and releases the locked member 123, completing the unlocking.

It is to be understood that the locking assembly 15 enables the moving assembly 12 to be locked in the holding groove 110 when it is not required to be used, and when it is required to be used it is only necessary to unlock the moving assembly 12 by the locking assembly 15, and the moving assembly 12 can be released from the holding groove 110 in order to be put into use. At the same time, the locking assembly 15 has a simple structure and is easy to operate, making it easy to use.

Above, specific embodiments of the present application are described with reference to the accompanying drawings. However, those of ordinary skill in the art can understand that various changes and substitutions can be made to the specific embodiments of the present application without departing from the spirit and scope of the present application. These changes and substitutions fall within the scope of the present application.

What is claimed is:

1. An electronic device port ejection structure configured for connecting with an electronic device, the electronic device port ejection structure comprising:
a first mounting member configured to be connected to the electronic device, and provided with a holding groove comprising a first damping portion on an inner wall of the holding groove;
a moving assembly slidably in a first direction coupled to the first mounting member, wherein at least a portion of the moving assembly is slidable, relative to the first mounting member, into the holding groove; the moving assembly comprises a second damping portion, the second damping portion contacts with the first damping portion and is configured to decelerate a sliding speed of the moving assembly when the moving assembly slides relative to the first mounting member; and
a first resilient member configured to resist against the moving assembly to drive the moving assembly out of the holding groove.

2. The electronic device port ejection structure of claim 1, wherein the first resilient member comprises a first bending portion, a compression portion, and a second bending portion connected in sequence, the first bending portion is connected to the first mounting member, and the second bending portion is connected to the moving assembly.

3. The electronic device port ejection structure of claim 2, wherein the first bending portion and the second bending portion are rotatably relative to the compression portion to elastically deform the compression portion to resist against the moving assembly when the moving assembly slides relative to the first mounting member.

4. The electronic device port ejection structure of claim 1, wherein the moving assembly further comprises a second mounting member, the second damping portion comprises at least one first projection, the at least one first projection is disposed on the second mounting member, the at least one first projection rests against at least a side of the first mounting member along a second direction when the moving assembly slides relative to the first mounting member, the second direction intersects the first direction.

5. The electronic device port ejection structure of claim 4, wherein the second damping portion comprises a plurality of first projections spaced apart along the first direction.

6. The electronic device port ejection structure of claim 4, wherein the electronic device port ejection structure further comprises a limit assembly, the limit assembly is configured to limit movements of the moving assembly in the first direction.

7. The electronic device port ejection structure of claim 6, wherein the limit assembly comprises a limit member, the limit member is connected to the first mounting member.

8. The electronic device port ejection structure of claim 7, wherein the second mounting member is provided with a limit hole, the limit member is configured to rest against a wall of an aperture of the limit hole along the second direction, and the limit member is movable in the limit hole along the first direction.

9. The electronic device port ejection structure of claim 7, wherein along a third direction, the limit member is configured to resist the second mounting member, the third direction intersects each of the first direction and the second direction.

10. The electronic device port ejection structure of claim 1, wherein the first damping portion comprises at least one second projection, the at least one second projection is disposed on the first mounting member, the at least one second projection rests against at least a side of the moving assembly along a second direction when the moving assembly slides relative to the first mounting member, the second direction intersects the first direction.

11. The electronic device port ejection structure of claim 10, wherein the first damping portion comprises a plurality of second projections spaced apart along the first direction.

12. The electronic device port ejection structure of claim 1, further comprising a locking assembly, wherein the moving assembly comprises a locked member, the locking assembly locks the locked member along the first direction when the locked member is moved to be partially located within the locking assembly; when the locked member move further into the locking assembly, the locking assembly unlocks the locked member and the locked member is releasable from the locking assembly.

13. The electronic device port ejection structure of claim 1, wherein the holding groove is disposed on an end surface of an end of the first mounting member along the first direction, and the holding groove extends along the first direction and does not penetrate through the first mounting member.

14. The electronic device port ejection structure of claim 2, wherein the first resilient member is disposed within the holding groove, the first bending portion is attached to an inner wall of the holding groove, and the second bending portion is directly attached to the moving assembly or disposed in a path of the moving assembly, and the second bending portion resists against the moving assembly.

15. The electronic device port ejection structure of claim 1, wherein the first resilient member is a torsion spring.

16. The electronic device port ejection structure of claim 4, wherein along the first direction, the second mounting member slides relative to the first mounting member to move the moving assembly relative to the first mounting member.

17. The electronic device port ejection structure of claim 4, wherein the at least one first projection is integrally molded with the second mounting member, or the at least one first projection and the second mounting member are separately molded.

18. The electronic device port ejection structure of claim 1, wherein the second damping portion comprises a first projection, or the first damping portion comprises a second projection.

19. The electronic device port ejection structure of claim 6, wherein along the first direction, the limit assembly is movable within a predefined path.

20. The electronic device port ejection structure of claim 1, wherein the locking assembly comprises a housing, a locking member, a guide member, and a second resilient member;
the guide member is coupled to the locking member, the housing is provided with an accommodating groove, the locking member is partially accommodated within the accommodating groove, the second resilient member resists against the locking member;
along the first direction, the locked member rests against and is locked by the locking member, the second resilient member resists against the locking member to drive the locking member to move out of the accommodating groove;
the second resilient member is a spring or a compression spring;
the guide member is connected to the locking member, the housing is provided with a guide hole connected to the accommodating groove, the guide member is driven by the locking member to move in an extension direction of the guide hole.
